(19) United States
(12) Patent Application Publication
(10) Pub. No.: US 2025/0125285 A1
(43) Pub. Date: Apr. 17, 2025

(54) ELECTRICAL FUSE STRUCTURE

(71) Applicant: International Business Machines Corporation, Armonk, NY (US)

(72) Inventors: Ashim Dutta, Clifton Park, NY (US); Chih-Chao Yang, Glenmont, NY (US); Brandon Noland Canedy, Cohoes, NY (US)

(21) Appl. No.: 18/486,526

(22) Filed: Oct. 13, 2023

(51) Int. Cl. H01L 23/62; H01H 69/02; H01H 85/02; H01H 85/044

(52) U.S. Cl. CPC H01L 23/62; H01H 69/02; H01H 85/0241; H01H 85/044; H01H 2085/0283; H01H 2229/016; H01H 2229/034

(57) ABSTRACT

An electrical fuse for an integrated circuit (IC). The electrical fuse includes a dielectric material substrate, and at least one line of conducting material located in the dielectric material substrate. Each of the at least one line of conducting material includes a first conductive structure, a second conductive structure, and a fuse element extending horizontally between the first and second conductive structures. The fuse element has a height that is less than the height of the first and second conductive structures.

### BACKGROUND

The present disclosure relates to semiconductor devices. More particularly, the present disclosure provides an electrical fuse (eFuse) that can be used in a wide range of critical dimensions and can be scaled to smaller dimensions.

Fuses are utilized within integrated circuit (IC) devices for a variety of purposes, such as to program certain functionality into the IC devices, to enable or disable various devices, etc. Such structures can actually make or break electrical connections (such as physically destroyable fuses or anti-fuses) or the structures can be what are known as “eFuses,” which simply provide a different electrical resistance value depending upon whether they are programmed (blown) or not.

### SUMMARY

According to some embodiments of the disclosure, there is provided an electrical fuse for an integrated circuit (IC). The electrical fuse includes a dielectric material substrate, and at least one line of conducting material located in the dielectric material substrate. Each of the at least one line of conducting material includes a first conductive structure, a second conductive structure, and a fuse element extending horizontally between the first and second conductive structures. The fuse element has a height that is less than the height of the first and second conductive structures.

According to some embodiments of the disclosure, there is provided an electrical fuse for an IC. The electrical fuse includes a dielectric material substrate, a first line of conducting material located in the dielectric material substrate, and a second line of conducting material located in the dielectric material substrate located above the first line of conducting material. The first line of conducting material includes a first conductive structure, a second conductive structure, and a first fuse element extending horizontally between the first and second conductive structures. The first fuse element has a height that is less than the height of the first and second conductive structures. The second line of conducting material includes a third conductive structure, a fourth conductive structure, and a second fuse element extending horizontally between the third and fourth conductive structures. The second fuse element has a height that is less than the height of the third and fourth conductive structures.

According to some embodiments of the disclosure, there is provided a method of fabricating an electrical fuse. The method includes an operation of forming a line of conducting material in a dielectric substrate. The method also includes an operation of etching a middle portion of the line of conducting material and leaving behind a layer of the conducting material in the middle portion. The method also includes an operation of depositing a layer of dielectric material atop the etched line of conducting material. The method additionally includes an operation of patterning a first trench over a first portion of the line of conducting material located on a first side of the layer of the middle portion and a second trench over a second portion of the line of conducting material located on a second side of the layer of the middle portion. The method also includes an operation of filling the first and second trenches with a conductive material to form first and second conductive connectors.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 is a cross-sectional view of a step in fabrication of an electrical fuse (eFuse) structure, in accordance with an embodiment of the present disclosure.

FIG. 2 is a cross-sectional view of a subsequent step to the step shown in FIG. 1 in fabrication of the eFuse structure, in accordance with an embodiment of the present disclosure.

FIG. 3 is a cross-sectional view of a subsequent step to the step shown in FIG. 2 in fabrication of the eFuse structure, in accordance with an embodiment of the present disclosure.

FIG. 4 is a cross-sectional view of a subsequent step to the step shown in FIG. 3 in fabrication of the eFuse structure, in accordance with an embodiment of the present disclosure.

FIG. 5 is a cross-sectional view of a subsequent step to the step shown in FIG. 4 in fabrication of the eFuse structure, in accordance with an embodiment of the present disclosure.

FIG. 6 is a cross-sectional view of a subsequent step to the step shown in FIG. 5 in fabrication of the eFuse structure, in accordance with an embodiment of the present disclosure.

FIG. 7 is a cross-sectional view of an eFuse structure, in accordance with an embodiment of the present disclosure.

FIG. 8 is a flow diagram of a method of fabricating an eFuse, in accordance with an embodiment of the present disclosure.

While the disclosure is amenable to various modifications and alternative forms, specifics thereof have been shown by way of example in the drawings and will be described in detail. It should be understood, however, that the intention is not to limit the disclosure to the particular embodiments described. On the contrary, the intention is to cover all modifications, equivalents, and alternatives falling within the spirit and scope of the disclosure.

### DETAILED DESCRIPTION

Aspects of the present disclosure relate generally to semiconductor structures. More particularly, the present disclosure provides an electrical fuse (eFuse) that can be used in a wide range of critical dimensions and can be scaled to smaller dimensions. While the present disclosure is not necessarily limited to such applications, various aspects of the disclosure can be appreciated through a discussion of various examples using this context.

Electrically programmable fuses or electrical fuses, also called “eFuses,” have become popular recently, because of the circuit and systems design flexibility that they provide. The eFuse can be programmed even when the chip is mounted in the package and installed in the system. For example, customers can tailor a design to the specific needs of the application after the product is installed in the field. The eFuse also enables the freedom to alter the design, or fix problems that may occur during the life of the product.

Electrical fuses (eFuses) are used in the semiconductor industry to implement array redundancy, field programmable arrays, analog component trimming circuits, and chip identification circuits, for example. A conventional fuse link dimension can be limited by allowable photolithographic minimal dimensions. Programming of eFuses can typically take a substantial amount of current, which is undesirable in current technology node devices using low driving current. In addition, a programming transistor takes up space in a semiconductor chip, as well as power consumption.

One example of a fuse element includes a two-dimensional (2D) dog-bone shaped fuse element. Such a dog-bone shaped fuse element includes a small cross-sectional area located between a cathode pad and an anode pad.

Increased local current density can be obtained by an eFuse by modification of a plan-view layout of the eFuse. The increase of local current density can improve process control and can result in increased programming efficiency.

Embodiments of the present disclosure relate to eFuses, and methods of forming eFuses, for semiconductor devices. An advantage of the eFuse structure disclosed herein is that the structure can be used for a wide range of critical dimensions and can be scaled to smaller dimensions. Another advantage of the eFuse structure disclosed is that standard photolithography can be used to pattern and fabricate a final eFuse structure link that can be smaller than normal allowable photolithography minimum dimensions. A manufacturing process used for the eFuse structure also can be compatible with current back-end-of-inline (BEOL) processing without additional changes in materials, masks and manufacturing processes. The resultant eFuse device can be easily integrated into logic devices. Yet another advantage is that the scalability of the eFuse structure is flexible and compatibility with possible future generations of integrated circuit (IC) chips.

It is to be understood that the present disclosure will be described in terms of a given illustrative architecture; however, other architectures, structures, substrate materials and process features and steps/blocks can be varied within the scope of the present disclosure. It should be noted that certain features cannot be shown in all figures for the sake of clarity. This is not intended to be interpreted as a limitation of any particular embodiment, or illustration, or scope of the claims.

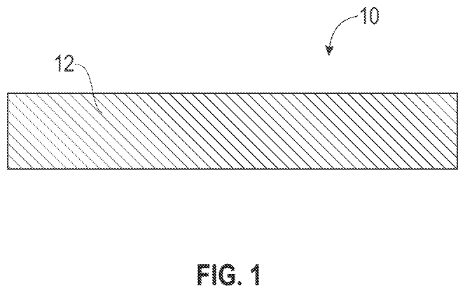

FIG. 1 is a cross-sectional view of a step in a fabrication of an eFuse structure 10, in accordance with an embodiment of the present disclosure. The eFuse structure 10 shown can be a portion of a larger semiconductor structure (not shown in full). The figure includes a first dielectric material layer 12. For purposes herein, a “dielectric” is a relative term that means a material or structure that allows substantially less (<95%) electrical current to flow than does a “conductor.” The dielectrics (i.e., insulators) mentioned herein can, for example, be grown from either a dry oxygen ambient or steam and then patterned. Alternatively, the dielectrics herein may be formed from any of the many candidate high dielectric constant (high-k) materials, including but not limited to silicon nitride, silicon oxynitride, a gate dielectric stack of silicon dioxide and silicon nitride, and metal oxides like tantalum oxide that have relative dielectric constants above that of silicon dioxide (above 3.9). The thickness of dielectrics herein may vary contingent upon the required device performance. Processes that can be used to lay the first dielectric material layer 12, for example, include chemical vapor deposition (CVD), plasma-enhanced chemical vapor deposition (PECVD), physical vapor deposition (PVD), atomic layer deposition (ALD), flowable chemical vapor deposition (FCVD), or a combination of these processes.

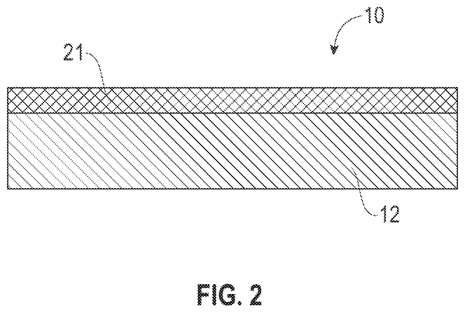

FIG. 2 is a cross-sectional view of a subsequent step to the step shown in FIG. 1 in fabrication of the eFuse structure 10, in accordance with an embodiment of the present disclosure. As shown, a line of conducting material 21 is applied atop the first dielectric material layer 12. A cross-section of one conducting material line 21 is shown in the figures herein, but the eFuse structure 10 can include a plurality of conducting material lines (like 21). A top-down view of the eFuse structure 10 may show a plurality of parallel conducting material lines (such as 21).

The conducting material line(s) 21 can be formed of any conductive material, such as polycrystalline silicon (polysilicon), amorphous silicon, a combination of amorphous silicon and polysilicon, and polysilicon-germanium, rendered conductive by the presence of a suitable dopant. Alternatively, the conducting material line(s) 21 herein can be one or more metals, such as copper, tungsten, hafnium, tantalum, molybdenum, titanium, or nickel, or a metal silicide, metal nitride or metal oxide. Also, alloys can be used for the conducting material, such as tantalum nitride, titanium nitride, tungsten nitride, and any other suitable alloys of metals. The conducting material line(s) 21 can be deposited, for example, using PVD, CVD, PECVD, plasma enhanced atomic layer deposition (PEALD), ALD, electroplating or any other technique known in the art.

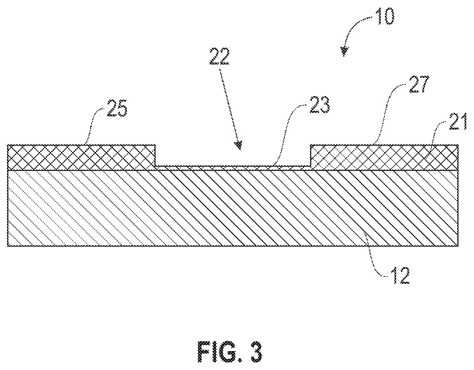

FIG. 3 is a cross-sectional view of a subsequent step to the step shown in FIG. 2 in fabrication of the eFuse structure 10, in accordance with an embodiment of the present disclosure. As shown, a portion of the conducting metal line 21 shown includes an etched portion 22 that is etched down, in a center or middle area/region, in order to leave behind a thin strip of conducting material, called a “fuse element” 23, adjacent the dielectric material layer 12. Dry or wet etching processes can be used to etch away a portion of the conducting material line 21. The etching process results in the fuse element 23 of the conducting metal line 21 extending between and connecting a first metal structure (i.e., a first terminal or first contact region) 25 to a second metal structure (i.e., a second terminal or second contact region) 27, that were originally portions of the conducting material line 21 as it appeared in the fabrication step in the process shown in FIG. 2. As shown, the fuse element 23 portion of the conducting material line 21 can be connected to the first and second metal structures 25, 27 at the bottom, or lower portion, of the first and second metal structures 25, 27. A thickness of the fuse element 23 can, for example, be within a range of 1-5 nm or <10% of a height of the metal lines, such as the metal line 21. In some embodiments, the fuse element 23 can be ten (10) to fifteen (15) times less in height (or thickness) than the first and second metal structures 25, 27.

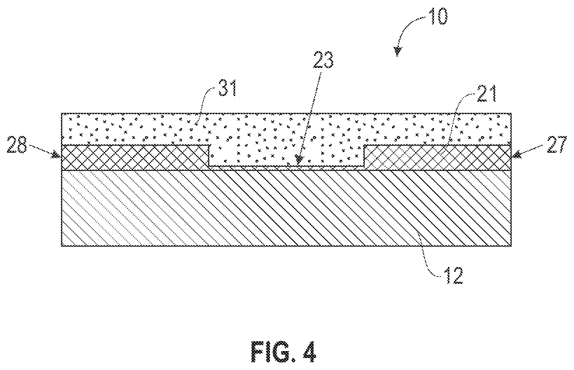

FIG. 4 is a cross-sectional view of a subsequent step to the step shown in FIG. 3 in fabrication of the eFuse structure 10, in accordance with an embodiment of the present disclosure. As shown, a second dielectric material layer 31 has been deposited atop the conducting material line 21, including the fuse element 23 and the first and second structures 25, 27. Processes that can be used to deposit the second dielectric material layer 31, for example, include CVD, PECVD, PVD, ALD, FCVD, or a combination of these processes. The second dielectric material layer 31 is shown planarized, which was completed after the deposition. Processes that can be used to planarize a dielectric material, such as chemical mechanical planarization (CMP), for example, can be used. The second dielectric material layer 31 can be made of the same material as the first dielectric material layer 12 or can be made of a different material. Some examples of such a dielectric material can include silicon oxide, silicon nitride, silicon carbide, silicon carbon nitride, silicon carbonitride, and a low-k material, etc.

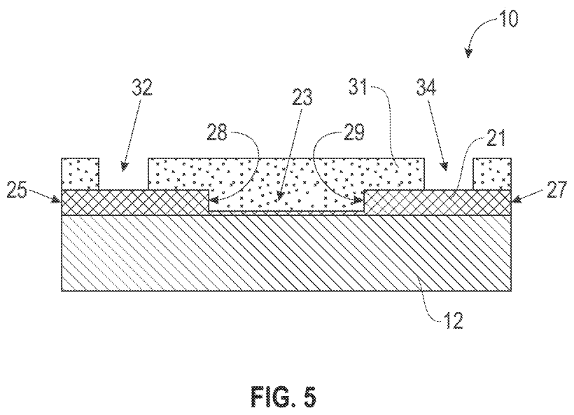

FIG. 5 is a cross-sectional view of a subsequent step to the step shown in FIG. 4 in fabrication of the eFuse structure 10, in accordance with an embodiment of the present disclosure. As shown, the second dielectric material layer 31 includes two dielectric trenches. A first dielectric trench 32 and a second dielectric trench 34 are shown patterned into the second dielectric material layer 31. The possible patterning processes that can be used include, for example, lithography followed by reactive ion etching (RIE). The first and second dielectric trenches 32, 34 are located above the first and second metal structures 25, 27, of the conducting material line 21, respectively, that are located on either side of the fuse element 23 of the conducting material line 21.

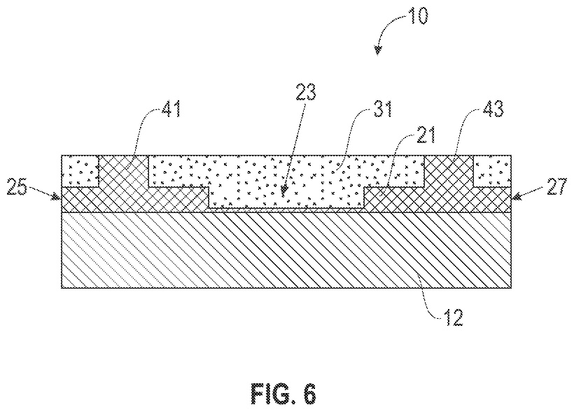

FIG. 6 is a cross-sectional view of a subsequent step to the step shown in FIG. 5 in fabrication of the eFuse structure 10, in accordance with an embodiment of the present disclosure. Using a metallization process, such as CVD, PECVD, PVD, ALD, or plating, for example, a first metal connection 41 and a second metal connection 43 are formed in the first and second trenches 32, 34, respectively (the first and second trenches 32, 34 shown in FIG. 5). The first metal connection 41 and the second metal connection 43 are located above the first and second metal structures 25, 27, respectively. After filling the first and second trenches 32, 34 with conducting material, a polishing process, such as CMP, can be used to allow top surfaces of the first and second connections 41, 43 to be flat or planar with respect to the top of the eFuse structure 10. Other processes for planarization, such as RIE or ion milling, for example, can be used alternatively.

The first and second metal connections 41, 43 can be made of a conducting material, such as those used for the conducting metal line 21, for example, and listed herein above. The conducting material line 21 and the first and second metal connections 41, 43 can be made of the same conducting material in the eFuse structure 10 or can be made of different conducting materials.

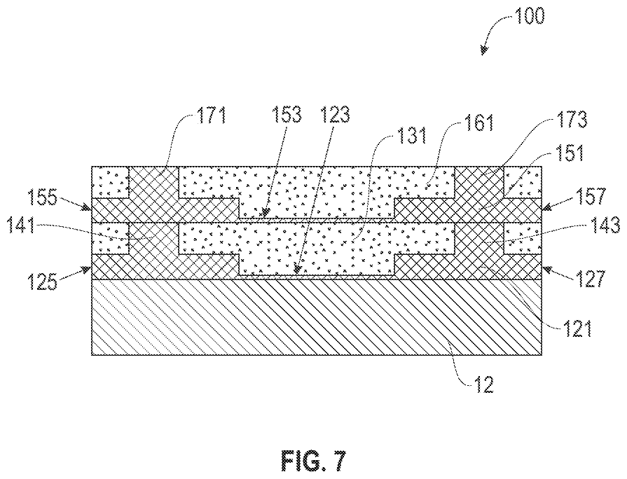

The eFuse structure 10 of FIG. 6 is one example of an eFuse, in accordance with an embodiment of the disclosure, that can be used in a semiconductor structure (not shown). FIG. 7 is another embodiment of an eFuse structure 100 of the disclosure that includes multiple fuse elements (in particular, two (2) are shown). Other numbers of fuse elements are also contemplated, however. The eFuse structure 100 includes two layers of structure each including a fuse element. The steps described herein above with regard to fabrication of the eFuse structure 10 also applies to the eFuse structure 100 of FIG. 7 and will not be described again. As shown, the eFuse structure includes a first dielectric material layer 12. An etched first conducting material line 121 includes a first metal structure 125, a second metal structure 127, and a first fuse element 123 located therebetween. A second dielectric material layer 131 was deposited on the first conducting material line 121 (and 125, 127). Two trenches previously formed in the second dielectric material layer 131 is shown filled with a conducting material to form a first metal connection 141 and a second metal connection 143 that is located above the first and second metal structures 125, 127, respectively. Atop the second dielectric material layer 131 and first and second metal connections 141, 143 is a second conducting metal line 151, which is shown etched to include a third metal structure 155, a fourth metal structure 157 and a second fuse element 153. Atop the second conducting material line 151 is a third dielectric material layer 161. Two trenches previously formed in the third dielectric material layer 161 are shown including a conducting material, which results in a third metal connection 171 and a fourth metal connection 173. Two trenches previously formed in the third dielectric material layer 161 are shown filled with a conducting material to form a third metal connection 171 and a fourth metal connection 173 that is located above the third and fourth metal structures 155, 157, respectively.

A thickness of the first fuse element 123 and the second fuse element 153 can, for example, be within a range of 1-5 nm or <10% of a height of the metal lines, such as the metal lines 121, 151, respectively. In some embodiments, the first fuse element 123 and the second fuse element 153 can be ten (10) to fifteen (15) times less in height (or thickness) than the first and second metal structures 125, 127, and the third and fourth metal structures 155, 157, respectively.

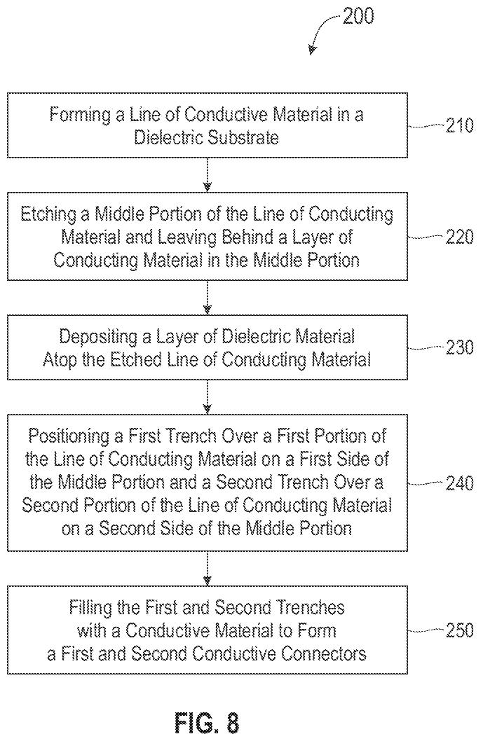

FIG. 8 is a flow diagram of a method 200 of fabricating an eFuse (i.e., eFuse 10), in accordance with an embodiment of the present disclosure. The method 200 includes an operation 210 of forming a line of conducting material 21 in a dielectric substrate 12. The method 200 includes another operation 220 of etching a middle portion 22 of the line 21 of conducting material and leaving behind a layer 23 of the conducting material 21 in the middle portion 22. A further operation 230 of the method 200 is depositing a layer of dielectric material 31 atop the etched line of conducting material 21. Yet another operation 240 is patterning a first trench 32 over a first portion 25 of the line of conducting material 21 located on a first side 28 of the layer of the middle portion 23 and a second trench 34 over a second portion 27 of the line of conducting material 21 located on a second side 29 of the layer of the middle portion 23. Another operation 250 is filling the first and second trenches 32, 34 with a conductive material to form first and second conductive connectors 41, 43.

In addition to the operations shown in FIG. 8, the method 200 can include an operation of planarizing the first and second conductive connectors 41, 43. The method can also include an operation of planarizing the layer of dielectric material 31, for example.

Another embodiment of a method of forming an eFuse (i.e., eFuse 100), can include additional operations to those shown in FIG. 8 and described above. For example, the method can include an operation of forming a second line of conducting material 151 on a dielectric layer 131 and first and second conductive connectors 141, 143. Another operation can be etching a middle portion of the second line of conducting material 151 and leaving behind a layer of the conducting material 153 of the second line of conducting material 151 in the middle portion of the second line of conducting material 151. Yet another operation can be depositing a second layer of dielectric material 161 atop the etched second line of conducting material 151. Another operation can be patterning a third trench over a first portion of the second line of conducting material 155 on a first side of the middle portion of the second line of conducting material 151 and a fourth trench over a second portion 157 of the second line of conducting material 151 on a second side of the middle portion of the second line of the conducting material 151. Another operation can be filling the third and fourth trenches with a conductive material to form third and fourth conductive connectors 171, 173. The method can include an operation of planarizing the third and fourth conductive connectors 171, 173. In addition, the method can include an operation of planarizing the second layer of dielectric material 161.

For purposes of this description, certain aspects, advantages, and novel features of the embodiments of this disclosure are described herein. The disclosed processes, and systems should not be construed as being limiting in any way. Instead, the present disclosure is directed toward all novel and nonobvious features and aspects of the various disclosed embodiments, alone and in various combinations and sub-combinations with one another. The processes, and systems are not limited to any specific aspect or feature or combination thereof, nor do the disclosed embodiments require that any one or more specific advantages be present, or problems be solved.

Although the operations of some of the disclosed embodiments are described in a particular, sequential order for convenient presentation, it should be understood that this manner of description encompasses rearrangement, unless a particular ordering is required by specific language set forth below. For example, operations described sequentially can in some cases be rearranged or performed concurrently. Moreover, for the sake of simplicity, the attached figures may not show the various ways in which the disclosed processes can be used in conjunction with other processes. Additionally, the description sometimes uses terms like “provide” or “achieve” to describe the disclosed processes. These terms are high-level abstractions of the actual operations that are performed. The actual operations that correspond to these terms can vary depending on the particular implementation and are readily discernible by one of ordinary skill in the art.

As used in this application and in the claims, the singular forms “a,” “an,” and “the” include the plural forms unless the context clearly dictates otherwise. Additionally, the term “includes” means “comprises.”

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

1. An electrical fuse for an integrated circuit, the electrical fuse comprising:
a dielectric material substrate; and
at least one line of conducting material located in the dielectric material substrate, wherein each of the at least one line of conducting material includes:
a first conductive structure;
a second conductive structure; and
a fuse element extending horizontally between the first and second conductive structures, wherein the fuse element has a height that is less than the height of the first and second conductive structures.

2. The electrical fuse of claim 1, wherein the fuse element extends horizontally between a bottom portion of each of the first and second conductive structures.

3. The electrical fuse of claim 1, wherein the fuse element is ten (10) to fifteen (15) times less in height than the first and second conductive structures.

4. The electrical fuse of claim 1, further comprising:
a first conductive connector that is located above the first conductive structure; and
a second conductive connector that is located above the second conductive structure.

5. The electrical fuse of claim 4, further comprising:
a layer of dielectric material surrounding the first conductive connector and the second conductive connector.

6. The electrical fuse of claim 1, wherein the conducting material is a metal.

7. An electrical fuse for an integrated circuit, the electrical fuse comprising:
a dielectric material substrate;
a first line of conducting material located in the dielectric material substrate, wherein the first line of conducting material includes:
a first conductive structure;
a second conductive structure; and
a first fuse element extending horizontally between the first and second conductive structures, wherein the first fuse element has a height that is less than the height of the first and second conductive structures; and
a second line of conducting material located in the dielectric material substrate located above the first line of conducting material, wherein the second line of conducting material includes:
a third conductive structure;
a fourth conductive structure; and
a second fuse element extending horizontally between the third and fourth conductive structures, wherein the second fuse element has a height that is less than the height of the third and fourth conductive structures.

8. The electrical fuse of claim 7, further comprising:
at least one additional line of conducting material located atop the second line of conducting material.

9. The electrical fuse of claim 7, wherein the first fuse element extends horizontally between a bottom portion of each of the first and second conductive structures, and the second fuse element extends horizontally between a bottom portion of each of the third and fourth conductive structures.

10. The electrical fuse of claim 7, wherein the first fuse element is ten (10) to fifteen (15) times less in height than the first and second conductive structures, and the second fuse element is ten (10) to fifteen (15) times less in height than the third and fourth conductive structures.

11. The electrical fuse of claim 7, further comprising:
a first conductive connector that is located above the first conductive structure;
a second conductive connector that is located above the second conductive structure;
a third conductive connector that is located above the third conductive structure; and
a fourth conductive connector that is located above the fourth conductive structure.

12. The electrical fuse of claim 11, further comprising:
a first layer of dielectric material surrounding the first conductive connector and the second conductive connector; and
a second layer of dielectric material surrounding the third conductive connector and the fourth consecutive connector.

13. The electrical fuse of claim 7, wherein the conducting material is a metal.

14. A method of fabricating an electrical fuse, the method comprising:
forming a line of conducting material in a dielectric substrate;
etching a middle portion of the line of conducting material and leaving behind a layer of the conducting material in the middle portion;
depositing a layer of dielectric material atop the etched line of conducting material;
patterning a first trench over a first portion of the line of conducting material located on a first side of the layer of the middle portion and a second trench over a second portion of the line of conducting material located on a second side of the layer of the middle portion; and
filling the first and second trenches with a conductive material to form first and second conductive connectors.

15. The method of claim 14, further comprising:
planarizing the first and second conductive connectors.

16. The method of claim 14, further comprising:
planarizing the layer of dielectric material.

17. The method of claim 14, further comprising:
forming a second line of conducting material on the dielectric layer and the first and second conductive connectors;
etching a middle portion of the second line of conducting material and leaving behind a layer of the conducting material of the second line in the middle portion of the second line of conducting material;
depositing a second layer of dielectric material atop the etched second line of conducting material;
patterning a third trench over a first portion of the second line of conducting material located on a first side of the layer of the middle portion of the second line of conducting material and a fourth trench over a second portion of the second line of conducting material located on a second side of the layer of the middle portion of the second line of the conducting material; and
filling the third and fourth trenches with a conductive material to form third and fourth conductive connectors.

18. The method of claim 17, further comprising:
planarizing the third and fourth conductive connectors.

19. The method of claim 17, further comprising:
planarizing the second layer of dielectric material.

20. The method of claim 17, wherein the conducting material is a metal.
